(19) United States
(12) Patent Application Publication
(10) Pub. No.: US 2006/0065946 A1
(43) Pub. Date: Mar. 30, 2006

(54) Multi-doped semiconductor e-fuse

(75) Inventors: Freidoon Mehrad, Plano, TX (US); Richard Rouse, Santa Clara, CA (US); Robert B. Churchill, Allen, TX (US)

Correspondence Address: TEXAS INSTRUMENTS INCORPORATED, P O BOX 655474, M/S 3999, DALLAS, TX, 75265, US

(73) Assignee: Texas Instruments, Inc.

(21) Appl. No.: 10/954,926

(22) Filed: Sep. 30, 2004

(51) Int. Cl. H01L 29/00

(52) U.S. Cl. 257/530

(57) ABSTRACT

The present invention provides a multi-doped semiconductor e-fuse for use in an integrated circuit and a method of manufacture therefore. In one aspect, the semiconductor e-fuse 200 includes a semiconductor body 205 having a neck region 220 interposed a first portion 210 of the semiconductor body 205 and a second portion 215 of the semiconductor body 205. The semiconductor body 205 is doped with opposite type dopants, and a conductive layer 230 is located over and extends across the neck region 220 to electrically connect the first portion 210 with the second portion 215.

### TECHNICAL FIELD OF THE INVENTION

The present invention is directed, in general, to integrated circuits and, more specifically, to a multi-doped semiconductor e-fuse, a method of manufacture therefor, and an integrated circuit incorporating the multi-doped semiconductor e-fuse therein.

### BACKGROUND OF THE INVENTION

The pursuit of increasing quality, productivity and product yield within the semiconductor manufacturing industry is an ongoing endeavor. To that end, the industry has developed techniques to improve operative yield by “trimming” or electrically removing inoperable or defective memory or other circuits from the main circuit. In such instances, in addition to main memory arrays or circuits, the integrated circuit also includes redundant memory arrays or circuits that are laid out in a way so that they can be electrically incorporated into the integrated circuit design when the defective portions are detected. In the event that a given memory block is defective, that block can be effectively “trimmed” or electrically removed from the circuit by use of a fuse or a group of fuses that electrically disconnect the defective component from the main circuit. When a defective memory block or circuit is detected, the relevant fuse or fuses are “blown” to an open configuration such that the defective memory block or circuit is electrically removed from the circuit.

In the past, the fuses were blown by use of a laser. The laser was used to manually cut through the fuse to open it and thereby disconnect the defective component block from the main circuit. However, this process was not only slow and time consuming, but it created a substantial amount of contaminating by-products such that the wafer had to be cleaned after the appropriate number of fuses were cut. This additional cleaning step added yet more cost and time to the manufacturing processes.

To circumvent the problems associated with manually blowing the fuses with a laser, the industry developed a poly semiconductor e-fuse. A conventional poly semiconductor e-fuse typically consists of a polysilicon body doped with a single type of dopant. The dopant used in such conventional devices is an N-type dopant, such as arsenic or phosphorous, and in many cases both are used, and is necessary to obtain good metal silicidation on the poly e-fuse. The polysilicon e-fuse usually has a narrow neck region separating the two larger, doped body portions and the top surface of the polysilicon e-fuse is covered with a conductive layer, such as a metal silicide. As mentioned above, the polysilicon e-fuse is positioned within the circuit such that when it is opened or blown, it disconnects the defective component from the main circuit. A logic algorithm is then used to direct the data stream to the redundant memory block or circuit. The fuse is blown by applying a relatively high voltage to the polysilicon e-fuse such that the conductive layer over the neck region melts. In most some instances, the underlying body portion of the polysilicon e-fuse also blows such that the two portions of the polysilicon e-fuse are completely and physically separated from each other.

However, in some instances, the body portion of the does not physically separate completely. This can cause problems because the body portion of the polysilicon e-fuse is conductive due to the N-type dopant within the body. As such, even though the conductive layer has physically separated and a portion of the body may have partially separated, a remaining, un-blown body portion may still exist, and if so, it may be capable of conducting enough current such that the fuse still functions as a closed fuse. This, in turn, causes the trimming effort to fail.

Accordingly, what is needed in the art is a semiconductor e-fuse that does not experience the difficulties associated with the prior art devices and methods.

### SUMMARY OF THE INVENTION

To address the above-discussed deficiencies of the prior art, the present invention provides a multi-doped semiconductor e-fuse for use in an integrated circuit. In one embodiment, the semiconductor e-fuse includes a semiconductor body having a neck region interposing a first portion of the semiconductor body and a second portion of the semiconductor body. The semiconductor body is doped with opposite type dopants, and a conductive layer is located over and extends across the neck region to electrically connect the first portion with the second portion.

In another embodiment, there is provided a method for manufacturing a multi-doped semiconductor e-fuse for use in an integrated circuit. The method includes forming a semiconductor body having a neck region interposing a first portion of the semiconductor body and a second portion of the semiconductor body, doping the semiconductor body with opposite type dopants, and forming a conductive layer over and extending across the neck region that electrically connects the first portion with the second portion.

In yet another embodiment, the present invention provides an integrated circuit that incorporates a semiconductor e-fuse therein. In this particular embodiment, the integrated circuit includes transistors, a memory interface, a main memory array associated with the transistors and the memory interface, and a redundant memory array associated with the memory interface. In one aspect the semiconductor e-fuse includes a semiconductor body having a neck region interposing a first portion of the semiconductor body and a second portion of the semiconductor body wherein the semiconductor body is doped with opposite type dopants. It further includes a conductive layer that is located over and extends across the neck region. The e-fuse forms an electrical connection between a memory interface and the main memory array. Interlevel dielectric layers are located over the transistors, and interconnects located within the interlevel dielectric layers contact the transistors, memory interface, the main memory array, the redundant memory array, and the semiconductor e-fuse to form an operational integrated circuit.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 is a highly schematic overhead view of a circuit layout showing how the semiconductor e-fuses might be associated with different components of an integrated circuit;

FIG. 2A is an overhead view of one embodiment of a multi-doped semiconductor e-fuse;

FIG. 2B is a sectional view of the embodiment of FIG. 2A taken through line B-B illustrating the doping layout and the formation of a PN junction and a reversed biased configuration;

FIG. 2C is an overhead view of another embodiment of a multi-doped semiconductor e-fuse wherein the neck region is doped with a different dopant type than the end portions of the fuse;

FIG. 2D is a sectional view of the embodiment of FIG. 2C taken through line D-D illustrating the doping layout and the formation of PN junctions;

FIG. 2E is an overhead view of another embodiment of a multi-doped semiconductor e-fuse wherein the semiconductor e-fuse is doped throughout with two different dopant types; and

FIG. 2F is a sectional view of the embodiment of FIG. 2E taken through line F-F illustrating the doping layout.

### DETAILED DESCRIPTION

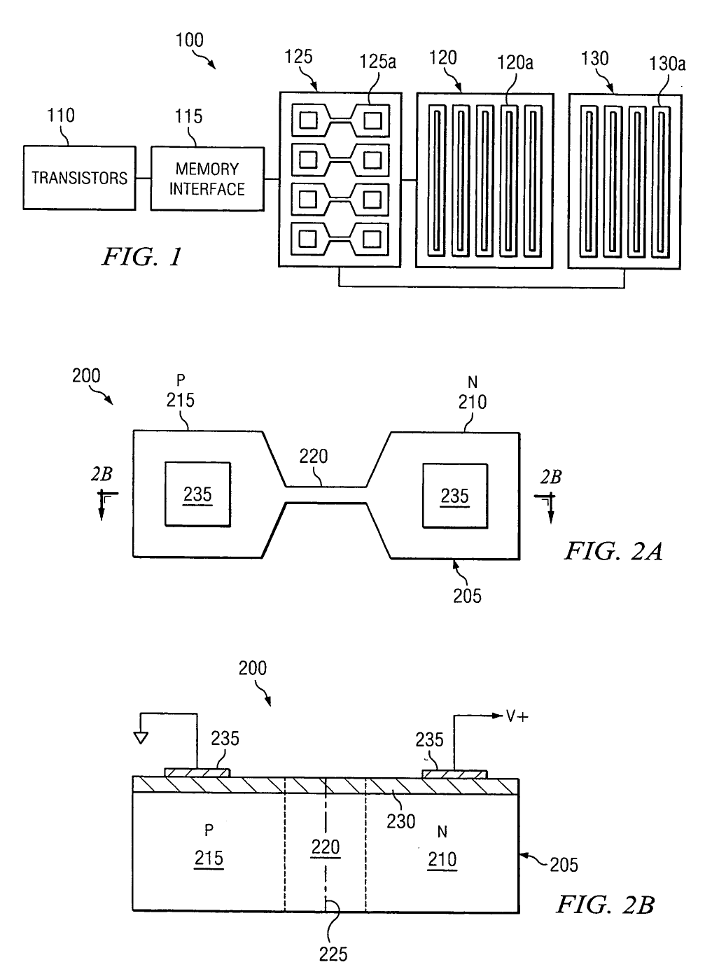

Referring initially to FIG. 1, illustrated is a highly schematic overhead view of an integrated circuit 100. In this particular embodiment, the integrated circuit 100 includes transistors 110, schematically represented by the box designated “transistors.” The transistors 110 may be of conventional design and include switching transistors, such as non-memory complementary metal oxide semiconductor (CMOS) transistors. The transistors 110 may be connected to a memory interface 115, which is also schematically represented by the box designated “Memory Interface.” The memory interface 115, may also be of conventional design and in one configuration may be a programed logic circuit used to direct data to a main memory array 120 that contains individual transistor blocks 120a configured as memory transistors, such as static random memory. Interposed the memory interface 115 and the memory array 120 is a fuse array 125 that includes the semiconductor e-fuses 125a, as provided by the present invention. It should be understood that the number of semiconductor e-fuses 125a within the fuse array 125 may vary, depending on design. The integrated circuit 100 also includes a redundant memory array 130 that contains individual transistor blocks 130a configured as memory transistors, such as static random memory. It should be noted that when the semiconductor e-fuses 125a are not blown, the memory interface 115 does not direct the data to the redundant memory array 130. However, when the semiconductor e-fuses 125a are blown, then the memory interface 115 directs the data to the redundant memory array 130.

The integrated circuit 100, as just described, is exemplary and schematic in nature only, and it should be understood that numerous circuit configurations might be employed. Moreover, it should be understood that those configurations are well within the skill of circuit designers, and as such, those who are skilled in the art would know how to incorporate and utilize the semiconductor e-fuses as provided by the present invention.

With a brief overview of the integrated circuit 100 having been given, its operation will now be briefly discussed. Again, it should be recognized that this discussion is meant to be exemplary only and the integrated circuit's 100 operation may vary, depending on design and its configuration. Upon completion of the fabrication of the integrated circuit 100, testing is typically conducted to insure proper operation of all components within the integrated circuit 100. In those instances where a defective circuit, such as one of the memory blocks 120a of the memory array 120, is not working properly, an appropriate voltage is applied to one or more of the semiconductor e-fuses 125a within the fuse array 125 to cause the appropriate fuse or number of fuses to blow and form an open circuit. This electrically disconnects the defective memory array 120, or memory block 120a from the memory interface 115.

The semiconductor e-fuses 125a may be electrically configured to electrically disconnect one of the memory blocks 120a or the entire memory array 120 from the memory interface 115, depending on how the integrate circuit 100 as been designed. The memory interface 115, then directs the data to one or more of the redundant memory blocks 130a within the entire redundant memory array 130, depending on how may of the memory blocks 120a of the main memory array 120 had to be disconnected. Because of the unique configuration of these semiconductor e-fuses, electrical disconnection of the defective memory block or array is assured, unlike the fuses provided by the prior art, as discussed above. As such, the problems associated with those prior art fuses are avoided.

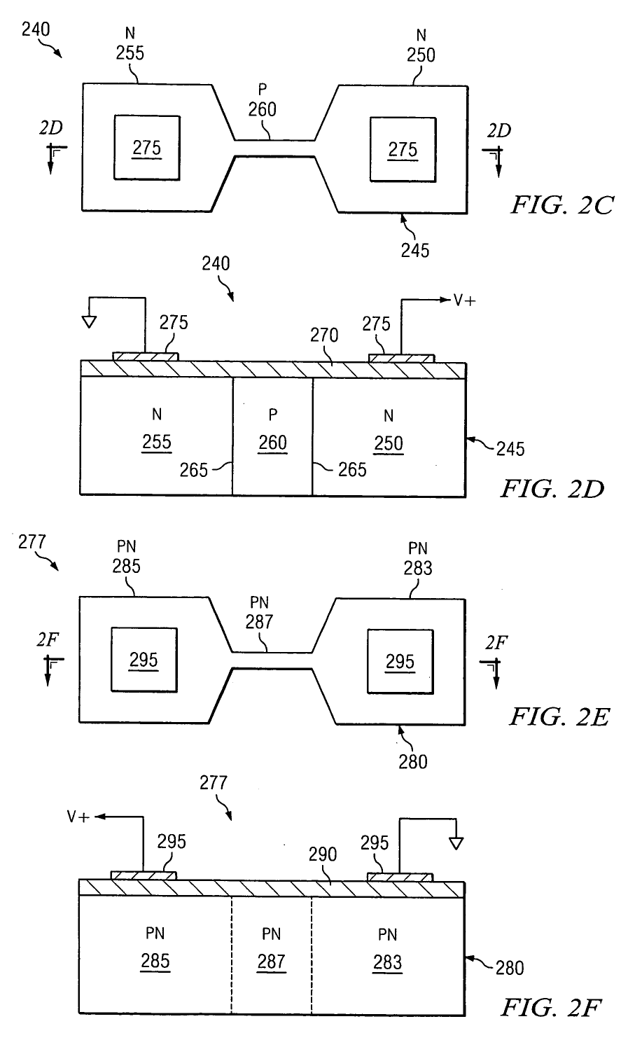

Turning now to FIG. 2A, there is illustrated an overhead view of one embodiment of a multi-doped semiconductor e-fuse 200 as provided by the present invention. In this particular embodiment, the multi-doped semiconductor e-fuse 200 includes a semiconductor body 205. The semiconductor body 205 may be any type of material used to form a semiconductor. For example, the semiconductor body 205 may be polysilicon, crystalline silicon, amorphous silicon, silicon germanium, or gallium arsenide, just to name a few. The semiconductor body 205 includes a first portion 210, a second portion 215 and a narrower neck region 220 interposed and joining the first and second portions 210, 215. As indicated, the first portion 210 is doped with an N-type dopant. The N-type dopant will vary, depending on the base material of the semiconductor body 205. For example, if the semiconductor body 205 is polysilicon, crystalline silicon or amorphous silicon, the N-type dopant would be arsenic, phosphorus, or both, while the second portion would be doped with a P-type dopant, such as boron. It should be understood, however, that the dopant schemes discussed with respect to the first and second portions 210, 215 may be reversed. Preferably, the semiconductor e-fuse 200 is located at the device level and is formed at the same time that the transistor gates are formed. Additionally, in an exemplary embodiment, the first and second portions 210, 215 are doped at the same time that the respective deep source/drain regions of the transistors are doped and preferably have the same respective dopant concentrations as the source/drain regions. However, in alternative embodiments, they may be formed and doped at a different time and with different dopant concentrations sufficient to form a semiconducting substrate. Moreover, the dopant concentrations may vary, but in an exemplary embodiment the dopant concentration for the N-type doped region for phosphorous may range from about 1E13 atoms/cm³ to about 5E15 atoms/cm² at an energy ranging from about 10 KeV to about 30 KeV, and for arsenic, the dopant concentration may range from about 1E15 atoms/cm³ to about 5E15 atoms/cm² at an energy ranging from about 25 KeV to about 45 KeV. The dopant concentration for the P-typed doped region may range from about 1E14 atoms/cm² to about 5E15 atoms/cm² at an energy ranging from about 3 KeV to about 10 KeV. One who is skilled in the art would know what implantation parameters and dopant concentrations to use for the different semiconductor materials mentioned above.

Referring now to FIG. 2B, there is illustrated a sectional view of a semiconductor e-fuse 200 of FIG. 2A taken through the line B-B showing the doping layout and the formation of a PN junction 225, schematically represented by the line located in the middle of the semiconductor e-fuse 200. Also, in this particular embodiment, the semiconductor e-fuse 200 is reversed biased, which, as explained below, provides certain advantages. While specific details of the full construction of this device are not fully shown or discussed, it should be understood that the semiconductor e-fuse 200, as mentioned above, is preferably formed on the transistor device level of the integrated circuit discussed above. In such instances, interlevel dielectric layers will overlie the semiconductor e-fuse 200, and it will be appropriately interconnected to the memory interface 115 and the main memory array 120 (FIG. 1) by way of conventional interconnects formed in those dielectric layers.

The first and second portions 210, 215 are also shown in this sectional view. Located over the surface of the semiconductor e-fuse semiconductor body 205 is a conductive layer 230. The conductive layer 230 extends over and across the neck region 220, which is represented in this figure by the dashed lines and electrically connects the first portion 210 to the second portion 215. The conductive layer 230, in an advantageous embodiment, may be a conventionally formed metal silicide layer, such as a cobalt silicide layer, a titanium silicide layer, or a nickel silicide layer. The presence of the dopants, as discussed above, assures good metal silicidation formation on the semiconductor e-fuse body 205. Other conductive layers, such as gold silver or copper, however, are also within the scope of the present invention. Conventionally formed electrical contacts 235 located on the conductive layer 230 are also shown. These electrical contacts 235 are used to provide a contact pad for via interconnects such that the semiconductor e-fuse 200 can be electrically designed in a reversed bias configuration wherein the N-typed doped first portion 210 is wired to a positive voltage and the P-typed doped second portion 215 is wired to ground, as shown.

In the embodiment illustrated in FIGS. 2A and 2B, a reversed bias configuration is particularly advantageous due to the opposed doping scheme present in this embodiment. Because the first and second portions 210 and 215 are oppositely doped, the device is capable of being configured in a reversed bias mode. This reversed biased configuration prevents the semiconductor e-fuse 200 from conducting through the semiconductor body 205 even in those instances where the semiconductor e-fuse 200 is not completely blown or physically divided. In operation, the appropriate voltage, which is within the knowledge of those skilled in the art, is applied to the conductive layer 230 to cause the conductive layer 230 to melt in the narrow neck region 220. This physically separates the conductive layer 230 into at least two portions. When this connection by way of the melting of the conductive layer 230 is broken, the current, as mentioned above is forced into the semiconductor body 205, but because of the opposite doping scheme and the reversed voltage bias, the current does not conduct through the semiconductor body. Thus, an open fuse is assured. This is a significant improvement over the prior art devices discussed above because in those devices, the polysilicon body is not oppositely doped, but is doped with a single type of dopant, and moreover, the device is not configured in a reversed biased mode. Thus, if the fuse does not experience complete separation, conduction through the polysilicon body can still occur, thereby causing the fuse to remain in a closed electrical configuration.

Turning now to FIG. 2C, there is illustrated an overhead view of another embodiment of a multi-doped semiconductor e-fuse 240, as provided by the present invention. In this particular embodiment, the multi-doped semiconductor e-fuse 240 also includes a semiconductor body 245, such as a polysilicon body, that includes a first portion 250, a second portion 255 and a narrower neck region 260 interposed and joining the first and second portions 250, 255. As with the previous embodiment, the semiconductor e-fuse 240 can be formed at the same time or at a different time as the transistor gate electrodes, which are not illustrated. The semiconductor e-fuse 240 of this embodiment is doped differently than the previous embodiment but can include the same type of dopants as previously discussed, depending on the type of semiconductor material used. In the illustrated embodiment, both the first and second portions 250 and 255 are doped with an N-type dopant, such as arsenic, phosphorus, or both, while the neck region 250 is doped with a P-type dopant, such as boron. Preferably, the first and second portions 250, 255 are doped at the same time that the N-type deep source/drain regions of the transistors are doped and have the same dopant concentrations as the N-type source/drain regions. However, in alternative embodiments, they may be doped at a different time and with different dopant concentrations sufficient to form a semiconducting substrate. Thus, the dopant concentrations may vary, but in an exemplary embodiment the dopant concentration for the N-type doped region for phosphorous may range from about 1E13 atoms/cm³ to about 5E15 atoms/cm² at an energy ranging from about 10 KeV to about 30 KeV, and for arsenic, the dopant concentration may range from about 1E15 atoms/cm³ to about 5E15 atoms/cm² at an energy ranging from about 25 KeV to about 45 KeV. The neck region 260 is preferably doped at the same time that the P-type deep source/drain regions for the transistors are doped and have the same dopant concentrations as the P-type source/drain regions. However, in alternative embodiments, they too may be doped at a different time and with different dopant concentrations sufficient to form a semiconducting substrate. In an exemplary embodiment, the dopant concentration for the P-typed doped region may range from about 1E14 atoms/cm² to about 5E15 atoms/cm² at an energy ranging from about 3 KeV to about 10 KeV. One who is skilled in the art would know what implantation parameters and dopant concentrations to use for the different semiconductor materials mentioned above.

Referring now to FIG. 2D, there is illustrated a sectional view of the semiconductor e-fuse 240 of FIG. 2C taken through the line D-D showing the doping layout and the formation of PN junctions 265, schematically represented by the solid lines located near the middle of the semiconductor e-fuse 240, which, in this particular embodiment also designates the neck region 260. Also, in this particular embodiment, a positive voltage is applied to the first portion 250, while the second portion 255 is grounded. However, unlike the previous embodiment, which had to be reverse biased in a specific configuration, this embodiment provides the added advantage that it does not matter which end of the semiconductor e-fuse 240 has the positive voltage and which end is grounded. This is due to the presence of the P-type dopant in the neck region 260 and the N-type dopants in the first and second portions 250, 255. Again, while specific details of the full construction of this device are not fully shown, it should be understood that the semiconductor e-fuse 240, as with the previous embodiment is preferably formed on the transistor device level of the integrated circuit. As such, interlevel dielectric layers will overlie the semiconductor e-fuse 240, and it will be appropriately interconnected by way of conventional interconnects formed in those dielectric layers.

The first and second portions 250, 255 are shown in this sectional view, and located over the surface of the semiconductor e-fuse semiconductor body 245 is a conductive layer 270. The conductive layer 270 extends over and across the neck region 260, as generally indicated, and electrically connects the first portion 240 with the second portion 245. The conductive layer 270, in an advantageous embodiment, may be a silicide layer, such as a cobalt silicide layer, a titanium silicide layer, or a nickel silicide layer. Other conductive layers, such as gold silver or copper, however, are also within the scope of the present invention. Electrical contacts 275 that are formed on the conductive layer 270 are also shown. These electrical contacts 275 are used to provide a contact pad for via interconnects, such that the semiconductor e-fuse 240 can be electrically connected to other parts of the integrated circuit.

As mentioned above, in the embodiment illustrated in FIGS. 2C and 2D, it does not matter which end of the semiconductor e-fuse 240 has the positive voltage and which is grounded. Because the first and second portions 250 and 255 are doped opposite to that of the neck region 260, which forms the PN junctions 265 in the middle of the device, a reverse bias configuration will exist no matter which end of the semiconductor e-fuse 240 is grounded. Again, this aspect of this particular embodiment is advantageous because it gives the designer more flexibility in designing layouts, and the doping configuration prevents the semiconductor e-fuse 240 from conducting through the semiconductor body 245 even in those instances where the semiconductor e-fuse 240 is not completely blown or physically divided, as discussed above. Thus, an open fuse is assured.

As was the case with the previous embodiment, this is a significant improvement over the prior art devices discussed herein because in those devices, the polysilicon body is not oppositely doped at any point, but is doped with the same type of dopant throughout, including the neck region. Moreover, the device cannot be configured in a reverse biased mode due to the single doping scheme. Thus, if the fuse does not experience complete separation, conduction through the polysilicon body can still occur, thereby causing the fuse to effectively remain in a closed electrical configuration.

Turning now to FIG. 2E, there is illustrated an overhead view of another embodiment of a multi-doped semiconductor e-fuse 277 as provided by the present invention. In this particular embodiment, the multi-doped semiconductor e-fuse 277 also includes a semiconductor body 280, as those discussed above, that includes a first portion 283, a second portion 285 and a narrower neck region 287 interposed and joining the first and second portions 283, 285. The semiconductor e-fuse 277 of this embodiment is doped differently than the previous embodiments. As indicated, the semiconductor body 280 is doped with both N-type and P-type dopants, as those discussed above, such that there is no effective PN junction within the semiconductor body 280. Similar to other embodiments, the semiconductor e-fuse 277 may be formed at the same time or at a different time as the transistor gate, and the first and second portions 283, 285 may be doped at the same time that the N-type and P-type deep source/drain regions of the transistors are doped and have the same dopant concentrations as those respective source/drain regions. However, in alternative embodiments, they may be doped at a different time and with different dopant concentrations sufficient to form a semiconducting substrate. Thus, the dopant concentrations may vary, but in an exemplary embodiment, the dopant concentration for the N-type doped region for phosphorous may range from about 1E13 atoms/cm³ to about 5E15 atoms/cm² at an energy ranging from about 10 KeV to about 30 KeV, and for arsenic, the dopant concentration may range from about 1E15 atoms/cm³ to about 5E15 atoms/cm² at an energy ranging from about 25 KeV to about 45 KeV. The dopant concentration for the P-typed doped region may range from about 1E14 atoms/cm² to about 5E15 atoms/cm² at an energy ranging from about 3 KeV to about 10 KeV. One who is skilled in the art would know what implantation parameters and dopant concentrations to use for the different semiconductor materials mentioned above.

Referring now to FIG. 2F, there is illustrated a sectional view of the semiconductor e-fuse 277 of FIG. 2E taken through the line F-F showing the doping throughout the semiconductor body 280. Also, in this particular embodiment, a positive voltage is applied to the second portion 285, while the first portion 283 is grounded. However, similar to the embodiment discussed with respect to FIG. 2D, because of the doping scheme, this embodiment also provides the added advantage that it does not matter which end of the semiconductor e-fuse 277 has the positive voltage and which end is grounded. This is due to the presence of both the P-type dopant and the N-type dopant being located throughout the semiconductor body 280. Again, while specific details of the full construction of this device are not fully shown, it should be understood that the semiconductor e-fuse 277, as with the previous embodiments, is preferably formed on the transistor device level of the integrated circuit. As such, interlevel dielectric layers will overlie the semiconductor e-fuse 277, and it will be appropriately interconnected by way of conventional interconnects formed in those dielectric layers.

The first and second portions 283, 285 are shown in this sectional view, and located over the surface of the semiconductor e-fuse semiconductor body 280 is a conductive layer 290. The conductive layer 290 extends over and across the neck region 287, as generally indicated by the dashed lines, and electrically connects the first portion 283 with the second portion 285. The conductive layer 290, in an advantageous embodiment, may be a silicide layer, such as a cobalt silicide layer, a titanium silicide layer, or a nickel silicide layer. Other conductive layers, such as gold silver or copper, however, are also within the scope of the present invention. Electrical contacts 295 formed on the conductive layer 290 are also shown. These electrical contacts 295 are used to provide a contact pad for via interconnects, such that the semiconductor e-fuse 277 can be electrically connected to other parts of the integrated circuit.

As mentioned above, in the embodiment illustrated in FIGS. 2E and 2F, it does not matter which end of the semiconductor e-fuse 277 has the positive voltage and which is grounded. Because the semiconductor body 280 is doped throughout with both types of dopants, the opposite dopants compensate for each other, which, in essence, substantially results in a zero or substantially zero net doping within the semiconductor body 280. This, in turn, results in a highly resistive semiconductor body 280. As such, if the semiconductor e-fuse 277 does not completely blow and separate physically, it will still effectively be an open fuse.

As with the previous embodiment, this aspect is advantageous because it gives the designer more flexibility in designing layouts, and the doping configuration prevents the semiconductor e-fuse 277 from conducting through the semiconductor body 280 even in those instances where the semiconductor e-fuse 277 is not completely blown or physically divided, as discussed above. Thus, an open fuse is assured.

As was the case with the previous embodiment, this is a significant improvement over the prior art devices discussed above because in those devices, the polysilicon body is not oppositely doped at any point, but is doped with the same type of dopant throughout, including the neck region, which results in the polysilicon body of the fuse being sufficiently conductive to cause the fuse to remain a closed electrical configuration, if the fuse does not experience complete separation.

Although the present invention has been described in detail, those skilled in the art should understand that they can make various changes, substitutions and alterations herein without departing from the spirit and scope of the invention in its broadest form.

What is claimed is:

1. A multi-doped semiconductor e-fuse for use in an integrated circuit, comprising:
a semiconductor body having a neck region interposed a first portion and a second portion of the semiconductor body, the semiconductor body being doped with opposite type dopants; and
a conductive layer located over and extending across the neck region that electrically connects the first portion with the second portion.

2. The multi-doped semiconductor e-fuse as recited in claim 1 wherein the first portion is doped with a first dopant and the second portion is doped with a second dopant wherein the first and second dopants are opposite type dopants.

3. The multi-doped semiconductor e-fuse as recited in claim 2 wherein the first dopant is an N-type dopant and the second dopant is a P-type dopant.

4. The multi-doped semiconductor e-fuse as recited in claim 3 wherein the N-type dopant is arsenic or phosphorous and the P-type dopant is boron.

5. The multi-doped semiconductor e-fuse as recited in claim 1 wherein the first portion and second portion are both doped with the opposite type dopants.

6. The multi-doped semiconductor e-fuse as recited in claim 1 wherein the first and second portions are doped with a first dopant and the neck region is doped with a second dopant wherein the first and second dopants are opposite type dopants.

7. The multi-doped semiconductor e-fuse as recited in claim 1 wherein the conductive layer is a silicide layer.

8. The multi-doped semiconductor e-fuse as recited in claim 9 wherein the semiconductor body is polysilicon and the silicide layer is a cobalt silicide layer, a titanium silicide layer, or nickel silicide layer.

9. The multi-doped semiconductor e-fuse as recited in claim 1 wherein a pn junction is located between the first portion and the second portion.

10. A method for manufacturing a multi-doped semiconductor e-fuse for use in an integrated circuit, comprising:
forming a semiconductor body having a neck region interposed a first portion of the semiconductor body and a second portion of the semiconductor body;
doping the semiconductor body with opposite type dopants; and
forming a conductive layer over and extending across the neck region that electrically connects the first portion with the second portion.

11. The method as recited in claim 10 wherein doping includes doping the first portion with a first dopant and doping the second portion with a second dopant wherein the first and second dopants are opposite type dopants.

12. The method as recited in claim 10 wherein the first dopant is an N-type dopant and the second dopant is a P-type dopant.

13. The multi-doped semiconductor e-fuse as recited in claim 12 wherein a dopant concentration of the N-type dopant ranges from about 1E13 atoms/cm³ to about 5E15 atoms/cm² and at an energy ranging from about 10 KeV to about 45 KeV, and a dopant concentration of the P-type dopant ranges from about 1E14 atoms/cm² to about 5E15 atoms/cm² and at an energy ranging from about 3 KeV to about 10 KeV.

14. The method as recited in claim 12 wherein the N-type dopant is arsenic or phosphorous and the P-type dopant is boron.

15. The method as recited in claim 11 wherein doping includes doping both the first and second portions with the opposite type dopants.

16. The method as recited in claim 11 wherein doping includes doping the first and second portions with a first dopant and doping the neck region with a second dopant wherein the first and second dopants are opposite type dopants.

17. The method as recited in claim 11 wherein forming the conductive layer includes forming a silicide layer.

18. The method as recited in claim 17 wherein the semiconductor body is polysilicon and the silicide layer is a cobalt silicide layer, a titanium silicide layer, or nickel silicide layer.

19. The method as recited in claim 11 wherein doping includes forming a pn junction between the first portion and the second portion.

20. An integrated circuit, comprising:
transistors;
a memory interface;
main memory arrays associated with the transistors and the memory interface;
redundant memory arrays associated with the memory interface;
a semiconductor e-fuse, including:
a semiconductor body having a neck region interposed a first portion of the semiconductor body and a second portion of the semiconductor body, the semiconductor body being doped with opposite type dopants; and
a conductive layer located over and extending across the neck region that electrically connects the first portion with the second portion, the semiconductor e-fuse forming an electrical connection between the main memory arrays and the memory interface;
interlevel dielectric layers located over the transistors; and
interconnects located within the interlevel dielectric layers and contacting the transistors, the main memory arrays and the redundant memory arrays and the semiconductor e-fuse to form an operational integrated circuit.

21. The integrated circuit as recited in claim 20 wherein the first portion is doped with a first dopant and the second portion is doped with a second dopant wherein the first and second dopants are opposite type dopants.

22. The integrated circuit as recited in claim 21 wherein the first dopant is an N-type dopant and the second dopant is a P-type dopant.

23. The integrated circuit as recited in claim 22 wherein the N-type dopant is arsenic or phosphorous and the P-type dopant is boron.

24. The integrated circuit as recited in claim 20 wherein the first portion and second portion are both doped with the opposite type dopants.

25. The integrated circuit as recited in claim 20 wherein the first and second portions are doped with a first dopant and the neck region is doped with a second dopant wherein the first and second dopants are opposite type dopants.

26. The integrated circuit as recited in claim 20 wherein the conductive layer is a silicide layer.

27. The integrated circuit as recited in claim 26 wherein the semiconductor body is polysilicon and the silicide layer is a cobalt silicide layer, a titanium silicide layer, or nickel silicide layer.

28. The integrated circuit as recited in claim 20 wherein a pn junction is located between the first portion and the second portion.

29. The integrated circuit as recited in claim 20 wherein the main memory arrays includes main memory blocks and the integrated circuit further includes a plurality of the semiconductor e-fuses and redundant memory arrays includes redundant memory blocks wherein each of the main memory blocks is connected to the memory interface at least one of the semiconductor e-fuses.

30. The integrated circuit as recited in claim 20 wherein the conductive layer located over the neck portion is configured to melt when an appropriate voltage is applied to the conductive layer to electrically disconnect the first portion from the second portion.
